(19) United States
(12) Patent Application Publication
(10) Pub. No.: US 2011/0265852 A1
(43) Pub. Date: Nov. 3, 2011

(54) OPEN ENCAPSULATED CONCENTRATOR SYSTEM FOR SOLAR RADIATION

(75) Inventors: Ruediger Loeckenhoff, Ludwigsburg (DE); Andreas Bett, Freiburg (DE); Maike Wiesenfarth, Freiburg (DE); Roy Segev, Mevaseret Zion (IL)

(73) Assignee: Fraunhofer-Gesellschaft Zur Foerderung Der Angewandten Forchung E.V., Munich (DE)

(21) Appl. No.: 12/737,573

(22) PCT Filed: Jul. 31, 2009
(86) PCT No.: PCT/EP2009/005575

§ 371 Date: Jul. 14, 2011

(30) Foreign Application Priority Data
Jul. 31, 2008 (DE) 10 2008 035 735.9

(51) Int. Cl. H01L 31/052

(52) U.S. Cl. 136/246

(57) ABSTRACT

The invention relates to an open concentrator system for solar radiation comprising a hollow mirror and a photovoltaic module comprising a plurality of solar cells disposed in the focus of said hollow mirror, the photovoltaic module being encapsulated by a housing. The housing is thereby configured such that it has a transparent cover at least in the region of the incident radiation reflected by the hollow mirror and such that this transparent cover is at a spacing from photovoltaic module, i.e. is situated in the cone of the incident radiation.

The invention relates to an open concentrator system for solar radiation comprising a hollow mirror and a photovoltaic module comprising a plurality of solar cells disposed in the focus of said hollow mirror, the photovoltaic module being encapsulated by a housing. The housing is thereby configured such that it has a transparent cover at least in the region of the incident radiation reflected by the hollow mirror and such that this transparent cover is at a spacing from the photovoltaic module, i.e. is situated in the cone of the incident radiation.

So-called open concentrator systems for solar radiation for current use have been increasingly gaining in importance in recent times. Such open concentrator systems are of interest in particular for photovoltaic applications where highly concentrated solar radiation is focused on a small area. In the focal point, there are situated a large number of solar cells which are connected to form a tightly packed photovoltaic module. The area of the solar cell module is of the order of cm² to a few 100 cm² in size. One possibility of concentrating the light is to reflect the solar radiation on correspondingly orientated mirrors. The radiation can thereby be concentrated up to over 1,000 times. The mirrors form a large, open concentrator system which tracks the position of the sun. For example an approx. 10 m² large parabolic mirror can be used, in the centre of which the tightly packed concentrator module is situated. In the Lajamanu power station (Northern Territory), concentrator systems have been installed since 2006, the hollow mirrors of which have an area of 129.7 m² and the photovoltaic receiver an area of 0.235 m² (see e.g. “Performance and reliability of multijunction III-V modules for concentrator dish and central receiver application”, “Proceedings of the 4^{th} World Conference on Photovoltaic Energy Conversion” 2006 in Waikoloa, Hi., USA). The solar radiation in the focus is concentrated 500 times.

However, the module must thereby be protected from the effects of weather, i.e. for example from penetrating moisture and dust particles and from mechanical stressing, such as e.g. hail, rain. The module must therefore be covered on the front-side. In order to keep radiation losses low, the material of the encapsulation must have as high transmission properties as possible and as low absorption and reflection properties as possible. Conventional solar module encapsulations are produced by using transparent sealing compounds and the module is partially covered by a glass plate (e.g. hardened, low-iron white glass). As described in Diaz, V., Pérez, J. M., Algora, C., Alonso, J. “Outdoor characterisation of GaAs solar cell under tilted light for its encapsulation inside optic concentrators” Isofoton (Spain), 17^{th} European Photovoltaic Solar Energy Conference, 2001, Germany, e.g. PMMA polymethylmethacrylate is used as sealing compound. Or the module is laminated with films (e.g. ethylene vinyl acetate (EVA) hot-melt adhesive film (Dr. Stollwerck, G. “Kunststoffverkapselung für Solarmodule” (Plastic material encapsulation for solar modules), Bayer Polymers AG, Leobener Symposium Polymeric solar materials, Germany, 2003). However, these are applications in which a flat module is irradiated with non-concentrated solar radiation (1 sun) or weekly concentrated sunlight (up to approx. 20 suns).

Furthermore, concentrator systems in which lenses are used for the concentration of the solar radiation are known in the state of the art. In these applications, the module is however encapsulated via the lens, i.e. closed concentrator systems in which the air space between the module and the concentrator is completely encapsulated are therefore involved. The encapsulation is hence not situated in a region with highly concentrated sunlight.

In the case of open concentrator systems where the radiation is concentrated e.g. via large hollow mirrors of 10 m² and more, the solar module with an area of cm² to a few 100 cm² is situated in a region with very high light intensity. The module consists of a plurality of solar cells which are connected tightly packed on a small surface. The construction of the module is similar to a silicon flat module, only the surface is significantly smaller in the case of a concentrator module and the module is irradiated not with 1 sun but approx. 1,000 suns. In order to avoid overheating, the concentrator solar module is generally provided with a very effective passive or active cooling.

In contrast to closed concentrator systems, the encapsulation of the photovoltaic module in open systems is irradiated by concentrated solar radiation. The concentrator tracks the sun so that the focal point during operation is always situated on the photovoltaic cell. Under specific conditions (e.g. when starting the operation, in the morning or after failure of the tracking system), the radiation cone must be realigned. For this purpose, the radiation cone must be guided over the edge of the encapsulation. This implies particularly high thermal stressing.

In order to keep efficiency losses of the system low, a high transmission of the solar radiation through the encapsulation must be ensured. Furthermore, heat is absorbed in the encapsulation, which must be taken into account in the construction and selection of materials. As far as possible, the shading of the mirror surface should not be increased and the beam path should not be interrupted.

A possible encapsulation of the module for avoiding the above-mentioned problems with a thin sheet of glass which is provided still possibly with a thin layer of a sealing compound, such as e.g. silicone, does however likewise entail disadvantages. In order to avoid the danger of overheating, the silicone layer laminated on a glass layer, at a 1,000 times concentration of the solar radiation, should not exceed a thickness of a few tenths of a millimetre. The following problems then consequently result:
Traditionally used transparent sealing compounds are typically temperature-resistant up to at most 200° C. The cooling of the sealing compound would have to be effected via the cooled, tightly packed module. Transparent sealing compounds have low heat conductivity. For example, the highly transparent silicone “Dow Cornings Sylgard 184” has a heat conductivity coefficient of 0.18 W/(m*K). A layer thickness of several tenths of a millimetre could result in cooling which is no longer adequate and overheating. This would result in discolouration, decomposition or scorching of the sealing compound.
Significant stresses occur due to differential thermal expansion. The linear expansion coefficient of silicone is higher than that of glass (e.g. “Dow Cornings Sylgard 184” 330 10⁻⁶ I/K and in comparison to 3.3 10⁻⁶ I/K of borosilicate glass (see http://www.duran-group.com/english/products/duran/properties/physik.html). This leads to rising and lowering of the glass plate and makes additional, lateral encapsulation of the glass plate, of the solar module and of the sealing compound difficult. Furthermore, the different thermal expansions of glass plate and sealing compound (silicone) lead to shear stresses in the silicone.
Silicone is susceptible to environmental influences (water, dirt). The silicone is open at the side on the edge of the glass plate. The silicone would have to be protected here by a further sealing compound. This is made difficult by the thermal stresses.

Starting herefrom, it is the object of the present invention to propose an encapsulation of a photovoltaic module in an open concentrator system, in which overheating of the encapsulation material is avoided as far as possible so that reliable operation of a concentrator system is consequently made possible, i.e. operation which ensures protection from the effects of weather. Furthermore, high light-permeability should be provided with low absorption and low reflection.

The object is achieved by the characterising features of patent claim 1.

The sub-claims reveal advantageous developments.

According to the invention, it is hence proposed that the photovoltaic module in an open concentrator system is encapsulated by a housing, the housing having a transparent cover at least in the region of the incident radiation reflected by the hollow mirror and the housing of the photovoltaic module being at a spacing from the transparent cover at least in the region of the transparent cover.

The photovoltaic module which is disposed in the focus inside the housing is a photovoltaic module, as is known per se from the state of the art, and consists of a plurality of solar cells which are connected to each other. For example, a plurality of chips, on which a large number of solar cells is disposed respectively, can be used, e.g. 24 chips with 600 individual solar cells. Preferably, the solar cells consist of silicon or semiconductors made of elements of the main group III and V of the periodic table and also germanium. Particularly high efficiencies can be achieved with multiple solar cells, in the case of which a plurality of solar cells with different band widths of the semiconductor are grown one above the other. As is likewise already known in the state of the art, the photovoltaic module is normally provided with electrical connections which are guided to the outside.

In the case of the hollow mirror which is used according to the invention in the open concentrator system, a parabolic mirror is preferably used.

It is now achieved by this configuration and arrangement according to the invention of the solar module inside the housing that the housing surrounding the solar module and the transparent cover here are not situated in the focus of the reflected radiation of the hollow mirror but rather in the cone. As a result of the fact that the transparent cover of the housing is now situated in the radiation cone, less radiation density also pertains in the transparent cover. The temperature in the encapsulation is therefore significantly reduced relative to the temperature which would occur in the focus of the reflected beams, i.e. in the photovoltaic module. A temperature only arises when a glass plate is in thermal equilibrium in fact at this position. Hence, it is also possible to select for example glass for the transparent cover, as a result of which high light-permeability and low absorption and also low reflection are achieved. A further advantage of the invention can be seen in the fact that the solar module is completely encapsulated by the housing so that protection from the effects of weather, dust, dirt, rain, moisture and hail, is also provided. The hermetic encapsulation permits in addition evacuation or a reduction in pressure. Due to these measures, excess pressure during heating of the enclosed gas is avoided. In addition, the encapsulation can be filled with an inert gas, which prevents chemical reactions, such as for example oxidation.

Alternatively, the encapsulation can be put under slight excess pressure with inert gas. In the case of slight leakage, gas would escape but no moist air would be drawn into the encapsulation from the outside. Because of the above-described problem, it is important that a pressure equalisation vessel is fitted in this construction.

The spacing between the transparent cover of the housing and the photovoltaic module is advantageously chosen such that the light intensity of the incident radiation in the region of the transparent cover of the housing is at least less by the factor 2, preferably by the factor 3, particularly preferred by the factor 5, and very particularly preferred by the factor 10, than in the region of the focus of the photovoltaic module.

The precise choice of the spacing is advantageously made such that the material of the encapsulation resists the increased temperatures during irradiation. If the transparent cover is formed for example from glass and the irradiated glass surface is five times the area in the focus, the radiation intensity is reduced correspondingly to ⅕. The heat input is also consequently correspondingly reduced. At a concentration of 1,000 suns in the focus, the radiation concentration is 200 suns on the glass surface. Simulation calculations produced a reduction in temperature in the glass by 270 K.

In the case of absorption of sunlight of 5%, an infrared emission degree a of 0.9 and the radiation intensity of 1,000 kW/m², a temperature is produced in the transparent cover in the case of the example of glass of 567° C. In the case of constant material properties and radiation intensity of 200 kW/m², the temperature is calculated at 297° C. The principle of a glass sheet in radiation equilibrium serves as the basis of the calculation. Heat transfer by convection is negligible. The glass sheet absorbs little in the spectral range of sunlight. It behaves as an almost black radiator for the energy radiation in the infrared. The radiation on the glass sheet is effected in both directions. Corresponding to this calculation, borosilicate glass could therefore be used as encapsulation material for example in the cover material.

In the case of the concentrator system according to the invention, it is preferred furthermore if the housing with the photovoltaic module is mounted on the hollow mirror if necessary with cooling via a carrier so that, as a result, exact adjustment in the cone of the reflected radiation from the hollow mirror is possible.

With respect to the configuration of the housing with the transparent cover, it is proposed according to a first embodiment of the invention that the housing itself and also the transparent cover consist of glass. For this embodiment, any glass housing can hence be used and the photovoltaic module can be disposed in the glass housing corresponding to the above-mentioned conditions. It is thereby preferred if the glass housing is configured in the form of a glass flask. The glass thereby preferably concerns borosilicate glass, a quartz glass or a glass ceramic. In the case of the above-described embodiment, the glass is hence situated in the radiation cone, i.e. in the region of low radiation density and hence outside the focus. The use of a glass flask with a curved surface confers in addition the further advantage that the radiation impinges virtually orthogonally on the glass surface as a result and hence is not deflected or reflected much. Due to a plane-parallel glass plate, a light beam is not deflected but merely displaced. The reflection is a requirement in the encapsulation techniques presented here and increases more with flat light incidence. Therefore the curved, transparent front cover here is advantageous. The electrical connections and possibly cooling water supply lines are provided with a radiation protector and can be guided to the outside for example via a glass tube melted onto the flask.

In a second embodiment of the invention, it is proposed that the housing is formed by a non-transparent, opaque housing wall and a transparent cover inserted in the region of the incident radiation. “Opaque” in the physical sense means “cloudy” or “not completely transparent”. However, also completely light-impermeable side walls are likewise conceivable. The housing and/or also the transparent cover can hereby be configured as double-walled with formation of a cooling water circulation. By using a cooling water circulation and hence cooling of the housing and/or of the transparent cover, a significant temperature reduction is ensured in addition. The side walls need not necessarily thereby be double-walled but can also be penetrated by cooling channels. Also passive cooling of the opaque side walls by convection and radiation is conceivable. The transparent cover can also consist again of glass, preferably of borosilicate glass, in this case. The non-transparent opaque housing wall preferably consists of metal, such as e.g. aluminium or copper. A favourable geometric embodiment is a double-walled tube, on the end-sides of which a double-walled cover is then fitted in the case of water cooling. An advantage of this embodiment can be seen in the fact that the cooling water circulation for the housing and the transparent cover can also be combined with a possibly present cooling water circulation for the photovoltaic module, i.e. a common cooling circulation for the photovoltaic module and the housing with the transparent cover is used. Of course, the opaque cover can also deviate from the cylindrical shape. It is not necessarily double-walled but can also be provided with cooling channels for a cooling circulation. Likewise a purely passive cooling by radiation and convection is possible. The active cooling of the opaque cover or of the opaque housing can also be sensible when the transparent front cover is designed with one wall.

The opaque parts of the housing can likewise have a reflective coating which reduces the heat input into the housing wall by reflection of the incident light to the outside.

The interior of the housing can thereby be filled e.g. with inert gas or else also evacuated. In fact, oxygen exclusion is not however absolutely required but moisture exclusion in the encapsulation is advantageous. For this purpose, a drying agent, such as e.g. silica gel, can be used and introduced into the housing. This drying agent has in fact a limited water absorption capacity but releases the moisture again at high temperature and can hence be regenerated for example during operation of the concentrator system. For this purpose, for example a container with silica gel could be fitted on the encapsulation such that it heats greatly during operation of the concentrator system. Suitable control of the air exchange can ensure that the air on the way to the outside passes the hot silica gel and thereby entrains moisture. On the way into the encapsulation, the air should, in contrast, pass cold silica gel and consequently be dried. Control of the airflow can be controlled actively via magnetic valves. Passive control is also conceivable via bimetal and non-return valves. The drying agent can likewise be accommodated in the air supply or discharge lines of the housing.

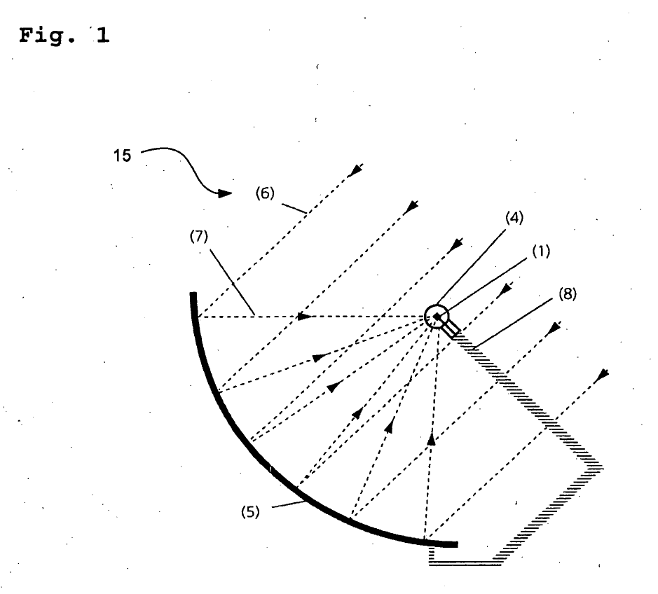

The invention is explained subsequently in more detail with reference to FIGS. 1 to 3.

FIG. 1 shows schematically the construction of an open concentrator system according to the invention,

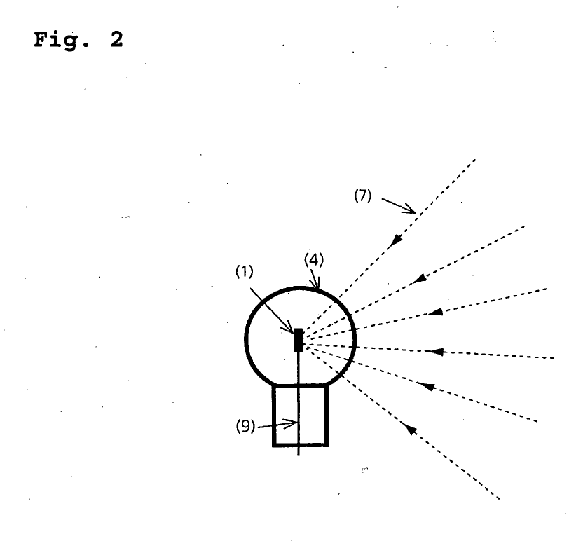

FIG. 2 shows in enlarged representation a housing with a photovoltaic module in the form of a glass flask,

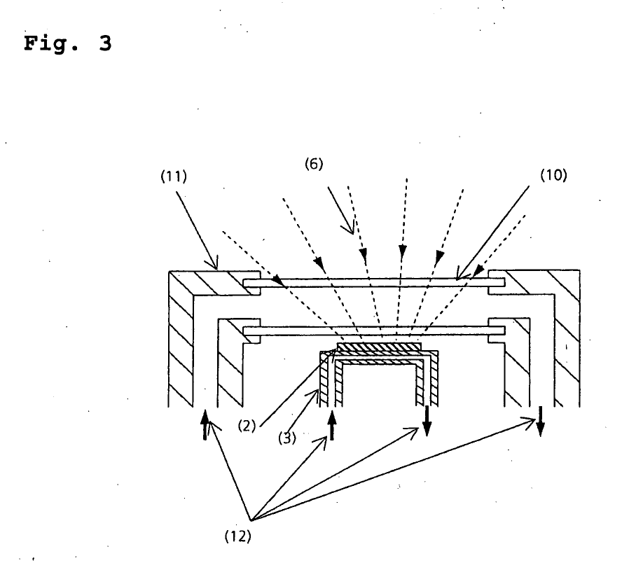

FIG. 3 shows a housing in a double-walled embodiment with an inserted glass sheet,

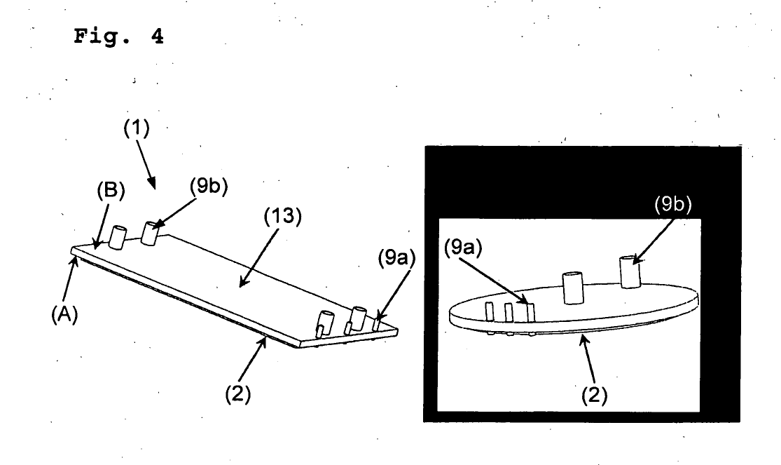

FIG. 4 shows two photovoltaic modules with rectangular or round shape and tightly packed photovoltaic cells, heat exchanger and cooling water connections,

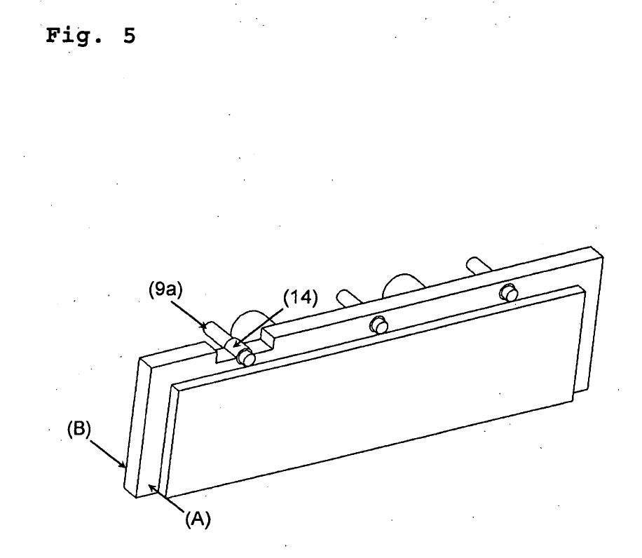

FIG. 5 shows a cross-section of the electrical conductor which leads through surface A and B,

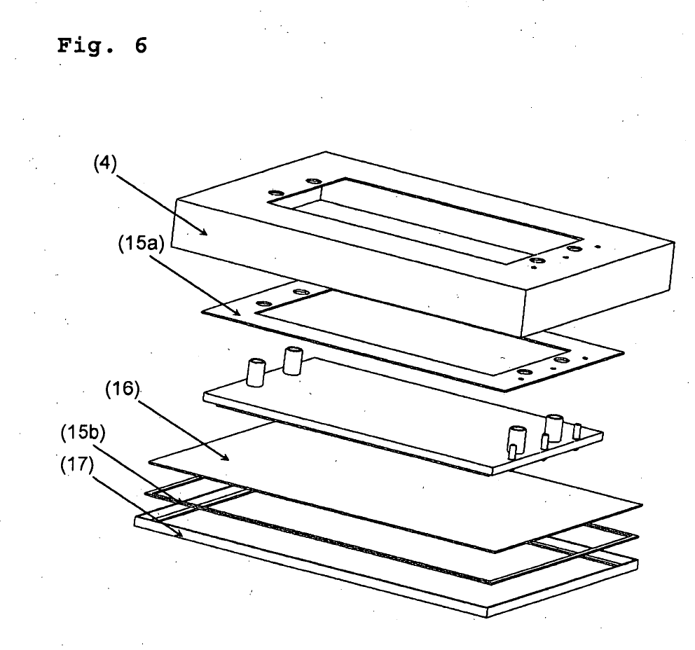

FIG. 6 shows the encapsulation of a rectangular module, and

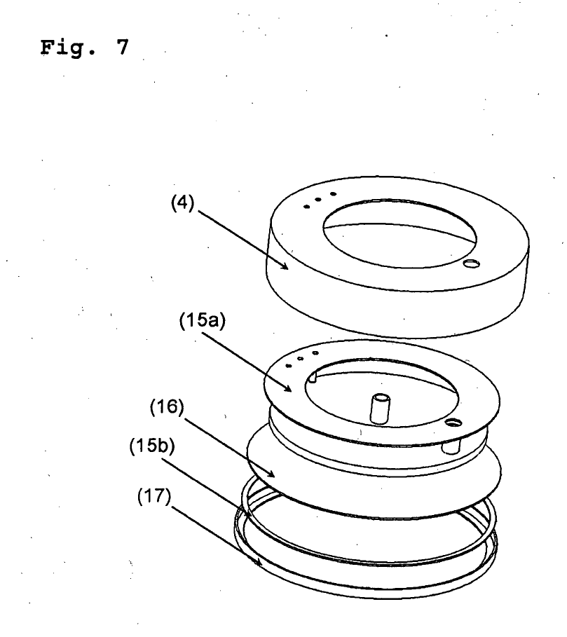

FIG. 7 shows the encapsulation of a round module.

FIG. 1 now shows the construction of an open concentrator system 15 according to the invention schematically in section. The concentrator system 15 in the example case of the embodiment according to FIG. 1 consists of a hollow mirror 5 which acts as concentrator. In FIG. 1, the beams incident on the concentrator are designated with 6 and the reflected beams with 7. The housing 4 in the embodiment case of FIG. 1 is configured in the shape of a glass flask. The photovoltaic module 1 is disposed in the housing 4 in the shape of a glass flask in the focus of the reflected beams. The housing 4 with the photovoltaic module 1 disposed in the housing is thereby mounted on the concentrator (hollow mirror) 5 via a carrier 8. The photovoltaic module 1 consists of a plurality of solar cells fitted on a cooling body and has electrical connections 9 (see FIG. 2 in this respect), via which the produced current is tapped.

The arrangement of the photovoltaic module 1 in the housing 4, here in the glass flask, can be deduced in detail from FIG. 2. The photovoltaic module 1 is thereafter protected by a glass cover 4. As emerges from FIG. 2, the glass is situated in the radiation cone, a smaller radiation density prevailing here than on the surface of the solar cells. The glass protector is distinguished by a curved surface. As a result, the radiation 7 impinges approximately orthogonally on the glass surface in the entire region of the glass protector and is deflected or reflected thus very little. The electrical connections and cooling water supply lines 9 are provided with a radiation protector and can be guided to the outside for example via a glass tube melted onto the base. In the case of a concentration of 200 suns on the wall of the glass flask of a wall thickness of 6 mm, borosilicate glass can be used for the encapsulation. In contrast to quartz glass, borosilicate glass is more economical. This means that the encapsulation can be produced also correspondingly economically. In the case of hermetic sealing of the encapsulation, moisture entry which can lead to condensation on the glass surface and degradation of the photovoltaic module 1 is precluded. The glass flask of the housing 4 is connected, in the embodiment of FIG. 2, via a connection tube to the carrier 8 (see FIG. 1 in this respect) and to the concentrator 5. Metal is used preferably for the carrier 8. As a result of the fact that metal is now used for the carrier 8 and the housing 4 consists of glass, a glass-metal transition is produced. Due to the low heat conduction in the glass and as a result of the fact that the flange is not situated directly in the focus, the temperature in the flange is low. Consequently, low mechanical stresses, which occur due to different heat expansion coefficients of the two materials, are produced at the connection point. The danger of breakage of the glass is consequently reduced.

FIG. 3 now shows, schematically in construction, a second embodiment for forming the housing and the transparent cover. In the embodiment according to FIG. 3 which is represented here partially in section, cooling water flows between the two glass layers 10. In order not to produce additional losses, for example deionised water should be used as cooling medium. The cooling water line 12 can be connected to the cooling water connection of the cooling body 3 of the photovoltaic cells and hence forms a cooling water circulation. This means that cooling water can cool for example firstly the photovoltaic cells 2 and subsequently the encapsulation. The sequence is preferably chosen such since in the encapsulation higher operating temperatures can occur.

Since the cooling water absorbs thermal energy, the cooling water temperature increases in the flow direction. The temperature of the cooling water depends upon the set volume flow, on the cooling water inlet temperature and the temperatures in the components to be cooled. In order to be able to use the thermal energy, the cooling water outlet temperature should be at least 80° C. It is thereby important that more possibilities for using the thermal energy are produced by higher temperatures. A higher temperature in the photovoltaic cell implies however also a slight reduction in efficiency and hence a reduced electrical input.

A further possibility for the construction is to separate the cooling water systems (encapsulation and photovoltaic module). This means that two cooling water circulations must be operated.

The photovoltaic module 1 is situated in a module housing 11 in the embodiment according to FIG. 3. As a function of the size, construction and material, it must also be water-cooled and in addition thermal energy can be obtained. With the water-cooled front-side, it can thereby form a constructional unit made of transparent material and hence the construction contributes merely slightly to the shading on the mirror surface. Consequently, this can be produced by placing the photovoltaic module 1 for example on a double-walled tube. In addition, preferably a hermetic metal-glass transition should be produced constructionally, in particular if the temperatures frequently change. The housing can also be produced from opaque material. Since merely a minimal radiation proportion is transmitted thus, more thermal energy can be absorbed by the cooling water and used.

During cooling of the encapsulation, radiation is absorbed in the cooling water. The absorption in the range of the infrared wavelength is thereby very high. Wavelengths higher than the energy band width are not used in the photovoltaic cells since the energy of the radiation does not suffice to raise electrons in the valency band of the semiconductor into the conduction band. Hence, this radiation cannot be used for current production. By absorption in the cooling water, the energy can however be used in addition for thermal production, as a result of which a significant increase in efficiency and total energy yield is made possible.

Further radiation losses result in the encapsulation due to absorption and reflection in the glass layers. Radiation losses due to reflection can however be reduced by an antireflection coating applied optionally on the encapsulation.

Special constructions of the photovoltaic module 1 are represented in detail in FIGS. 4 to 7. According to the embodiments of FIG. 4, the photovoltaic module is thereby either rectangular or round. The module 1 consists of tightly packed concentrator cells 2 and a heat sink 13, i.e. a cooling element, via which the heat can be dissipated. The geometric shape has at least two parallel but not necessarily plane-parallel surfaces A and B which are situated at a spacing of several millimetres. The module can have the shape of a rectangular prism or cylinder. The module 1 is thereby mounted directly on the encapsulation base 13 which acts as heat exchanger. Concentrator solar cells 2 (not shown) are fitted on the irradiated surface A. The side A is penetrated by electrical conductors 9a, at least two form the positive and negative electrical contact of the module. The conductors 9a are guided through the surfaces A and B and are insulated electrically from the module 1, secured mechanically and separated thermally by a liquid-impermeable and electrically insulated intermediate layer from the heat exchanger medium which is guided in the cooling water connections 9b. The conductors 9a are connected in a gas-tight manner to the surrounding construction. The leadthrough of the electrical conductors through the photovoltaic module 1 and the surfaces A and B is represented in detail in FIG. 5, the electrical insulation 14 of the conductors 9a being illustrated in detail. The construction can be designed such that the surface B (non-irradiated side) provides the access to the cooling water connections 9b and the electrical contacts 9a. The encapsulation and the module are thereby secured to each other in a permanently shaded region, e.g. on the underside of the heat exchanger 13.

FIGS. 6 and 7 show embodiments of the rectangular (FIG. 6) or round (FIG. 7) embodiments in detail for the encapsulations of the photovoltaic modules, i.e. the components which surround the photovoltaic module 1 and hence also the solar cells 2. For reasons of clarity, the solar cells 2 are not shown here but are configured according to the preceding embodiments and integrated in the concentrator system. The housing 4 protects the cells from the environment and the foreign substances thereof. The encapsulation housing 4 can be designed differently, e.g. as an open bulb, box or cylinder, and is connected to the photovoltaic module 1 via an air-tight construction on the surface B. The air-tight construction can be an integrated part of the module 1 or be soldered, glued or the like together with the module 1. However, it can also be able to be dismantled by holding the parts together mechanically (e.g. via screw connections) and via seals 15a and 15b (e.g. rubber seal made of an elastomer). The transition between housing 4 and module 1 is situated in the cooled region of the heat exchanger; no additional cooling is therefore required.

The entire encapsulation is formed in principle from the housing 4 and a transparent front glass sheet 16 or dome. The enclosed space is either evacuated, filled with inert gas (preferably at a lower pressure then atmospheric pressure), filled with air, the air being processed (e.g. drying apparatus), so that the quality is sufficient to avoid degradation of the construction, or is gas filled (e.g. nitrogen) and equipped with a pressure equalisation vessel in order to equalise the pressure rise which is produced by the volume expansion of the gas at increased temperature (e.g. expansion vessel).

The encapsulation housing 4 can be manufactured from metal.

The encapsulation fulfils the following requirements:
1. It has sufficient mechanical stability: the mechanical strength of the housing is so great that structural rigidity of the housing to external forces due to e.g. wind of approx. 10 m/s and movement due to tracking of the concentrator is maintained and can carry the weight of the photovoltaic module.
2. It is resistant to solar radiation which is concentrated up to approx. 1,000 times without ensuring active cooling.
3. It has good heat conduction properties (e.g. by treating the absorbing surfaces (increasing the reflection, good thermal conduction) or the use of heat exchangers), such that the heat can be dissipated in the case of faulty adjustment or errors/failure of the tracking.
4. It is equipped with a dismantleable, transparent, flat or rounded window plate 16, e.g. made of glass, through which concentrated radiation penetrates towards the solar cells.
5. A correspondingly shaded seal 15a, e.g. made of plastic material, serves as seal between window plate and housing.
6. The plastic material seal 15a is fitted such that the thermal expansion of the glass window is equalised, whilst the housing 4 is in addition closed in a gas-tight manner. As a result of the seal 15a, the input of stresses due to mechanical forces on the glass/housing is also minimised.
7. The plastic material seal 15a is cooled by contact with the housing.
8. The plastic material seal 15a is positioned such that it is never subjected to concentrated radiation (e.g. by shading elements, not shown).
9. The housing 4 is constructed such that the shading of the concentrator mirror surface by the housing 4 is minimised.
10. The window plate 16 has a spacing from the solar cells 2 so that the radiation intensity on the surface is reduced at least by the factor 2 or more. This means that the glass surface 16 is at least twice the size of the entire surface of the solar cells 2.

1-21. (canceled)

22. An open concentrator system for solar radiation comprising a hollow mirror and a photovoltaic module comprising a plurality of solar cells disposed in the focus of said hollow mirror, wherein the photovoltaic module is encapsulated by a housing, the housing having a transparent cover at least in the region of the incident radiation reflected by the hollow mirror and in that the photovoltaic module is at a spacing from the transparent cover at least in the region of the transparent cover of the housing.

23. The concentrator system according to claim 22, wherein the spacing between the transparent cover of the housing and the photovoltaic module is chosen such that the light intensity of the incident radiation in the region of the transparent cover of the housing is at least less by the factor 2 than in the region of the focus in the photovoltaic module.

24. The concentrator system according to claim 23, wherein the light intensity is less by the factor 3 than in the focus.

25. The concentrator system according to claim 22, wherein the transparent cover is curved at least in the region of the incident radiation.

26. The concentrator system according to claim 22, wherein the housing and the transparent cover consist of glass.

27. The concentrator system according to claim 26, wherein the glass is a glass flask.

28. The concentrator system according to claim 26, wherein borosilicate glass, glass ceramic or quartz is used as glass.

29. The concentrator system according to claim 22, wherein the housing consists of a non-transparent, opaque housing wall and a transparent cover inserted in the region of the incident radiation.

30. The concentrator system according to claim 29, wherein the housing, at least in the region of the opaque housing wall and/or at least in the region of the transparent cover, has a double-walled configuration with formation of a cooling circulation.

31. The concentrator system according to claim 30, wherein the opaque housing wall and/or the transparent cover respectively is penetrated at least in regions by at least one cooling channel.

32. The concentrator system according to claim 30, wherein the transparent cover is formed by glass.

33. The concentrator system according to claim 40, wherein borosilicate glass, glass ceramic or quartz is used as glass.

34. The concentrator system according to claim 30, wherein the opaque housing wall consists of metal, in particular aluminium and/or copper.

35. The concentrator system according to claim 30, wherein the housing consists of a double-walled tube and a double-walled transparent cover disposed on an end-side.

36. The concentrator system according to claim 22, wherein the photovoltaic module can be cooled via a cooling circulation.

37. The concentrator system according to claim 22, wherein the transparent cover is provided with at least one antireflection layer.

38. The concentrator system according to claim 31, wherein a common cooling circulation is provided for the photovoltaic module and the housing.

39. The concentrator system according to claim 22, wherein the photovoltaic module is formed from at least two solar cells which are connected to each other.

40. The concentrator system according to claim 22, wherein the photovoltaic module is selected from the group consisting of silicon flat modules, solar cells made of III-V semiconductors and solar cells based on germanium.

41. The concentrator system according to claim 22, wherein a drying agent is present inside the housing and/or in an air supply line to the housing, which drying agent serves for drying the gas inside the encapsulation and is regenerated by the heat of the concentrated light.

42. The concentrator system according to claim 22, wherein the housing has a reflecting coating in the region of the opaque housing wall.

43. The concentrator system according to claim 23, wherein the light intensity is less by the factor 5 in the focus.

44. The concentrator system according to claim 23, wherein the light intensity is less by the factor 10 than in the focus.

45. The concentrator system according to claim 34, wherein the metal is aluminium and/or copper.

46. The concentrator system according to claim 41, wherein the drying agent comprises a silica gel.
